(19) United States
(12) Patent Application Publication
(10) Pub. No.: US 2025/0292983 A1
(43) Pub. Date: Sep. 18, 2025

(54) MONITORING SYSTEM, REPARTITION ASSEMBLY, MONITORING PROCESS AND ASSOCIATED COMPUTER PROGRAM

(71) Applicant: Schneider Electric Industries SAS, Rueil-Malmaison (FR)

(72) Inventors: Abderrahmane Agnaou, Grenoble (FR); Emmanuel Doucet, Echirolles (FR); Laurent Goupil, La Tour du Pin (FR); Marta Crisanti, Grenoble (FR)

(73) Assignee: Schneider Electric Industries SAS, Rueil-Malmaison (FR)

(21) Appl. No.: 19/072,086

(22) Filed: Mar. 6, 2025

(30) Foreign Application Priority Data
Mar. 13, 2024 (FR) 2402505

(51) Int. Cl. H01H 71/04; H01H 9/18

(52) U.S. Cl. CPC H01H 71/04; H01H 9/18

(57) ABSTRACT

The present invention relates to a system for monitoring an electrical cabinet able to be connected between an electrical source (3) and a plurality of loads (5), the electrical cabinet (10) comprising a plurality of switching devices (20), each device comprising a movable member (22) configured to be displaced when an electrical fault is detected by the device or following a command from a user, each device being of one type from among the group consisting of: a circuit breaker type and a type other than a circuit breaker the system comprising at least one radar unit (32), configured to, when one of the movable members is displaced, emit an output signal representative of a speed of displacement of the movable member as well as a stroke of the movable member; and an electronic control module, configured to receive the output signal and determine the type of device to which the movable member associated with the output signal belongs.

### FIELD

The present invention relates to a monitoring system, a repartition assembly, a monitoring method and an associated computer program.

### BACKGROUND

It is known to monitor an armed or tripped state of certain switching devices, included in an electrical cabinet, in particular circuit breakers, in order to facilitate an intervention on the electrical cabinet when an electrical fault is detected. For this purpose, it is known to add a so-called Open Closed System Fault module to the devices to be monitored. However, an Open Closed System Fault module has to be added for each device to be monitored, which increases the cost of the electrical cabinet, and the installation of such an Open Closed System Fault module requires additional wiring, making them complex to install. Furthermore, in many cases, there is insufficient space in the electrical cabinet to install Open Closed System Fault modules on the switching devices to be monitored.

It is also known to monitor an armed or tripped state of devices in electrical cabinets via electromagnetic waves, for example in DE102012110246A1. Other monitoring systems are described in CA2783227A1, EP3731251A1, U.S. Pat. No. 6,020,821A1 and EP3920204A1.

### SUMMARY

The aim of the invention is therefore to propose a system for monitoring an electrical cabinet which is easier to install, less costly and requires less space than existing solutions.

To this end, the invention has as its object a system for monitoring an electrical cabinet, the electrical cabinet being able to be connected between an electrical source and a plurality of loads, the electrical cabinet comprising a plurality of switching devices, each device comprising a movable member configured to be displaced when an electrical fault is detected by the device or following a command from a user, each device being of a type from among the group consisting of: a circuit breaker type and a type other than a circuit breaker, the system comprising:
at least one radar unit, configured to, when one of the movable members is displaced, emit an output signal which is representative of a speed of displacement of the movable member as well as a stroke of the movable member;
an electronic control module, configured to receive the output signal and determine the type of device to which the movable member associated with the output signal belongs, and
a transmission module, configured to emit a message representative of the type determined by the electronic control module.

Thanks to the invention, it is possible to monitor several switching devices with a single monitoring system, by the use of at least one radar unit, which is capable of detecting a displacement of a movable member in a sufficiently wide area for several switching devices to be monitored simultaneously. The determination module ensures distinction between the circuit breaker type devices and the type other than circuit breaker devices, thus avoiding false alarms in the event of displacement of a movable element belonging to a non circuit breaker type device, in other words, in the event of tripping of a non circuit breaker type device.

The monitoring system of the invention is simple to install, since it does not need to be connected to each switching device to be monitored, and, for an equivalent number of switching devices to be monitored, takes up less space than known monitoring devices. Furthermore, it can be added once the electrical cabinet is already in use, without modifying the layout of the devices included in the cabinet.

According to other advantageous aspects of the invention, the system comprises one or more of the following features, taken alone or in any technically possible combination:
The electronic control module comprises:
a calculation unit configured to calculate, from the output signal, the speed of displacement and the stroke of the movable member associated with the output signal; and
a determination unit, configured to determine the type of device to which the movable member associated with the output signal belongs from the speed of displacement and the stroke calculated by the calculation unit.
The electronic control module comprises:
a calculation unit configured to calculate a metric from the output signal; and
a determination unit, configured to determine the type of device to which the movable member associated with the output signal belongs via an artificial intelligence model, the metric being an input variable of the model, the type of device to which the movable member associated with the output signal belongs being an output variable of the model.
The artificial intelligence model is a neural network or a random forest.
The output signal being further representative of a position within the cabinet of the device comprising the movable member associated with the output signal.
Each circuit breaker type device comprising a subtype, the electronic control module being further configured, when a movable member belonging to a circuit breaker type device displaces, to determine the subtype of the device to which the movable member associated with the output signal belongs.

The invention also relates to an assembly for distributing an electric current between a source and a load, the assembly comprising:
an electrical cabinet comprising an enclosure, the enclosure comprising two longitudinal walls extending parallel to a height axis, aligned relative to each other according to a width axis, and a plurality of switching devices, each device comprising a movable member configured to be displaced when an electrical fault is detected by the device or following a command from a user, each device being of a type from among the group consisting of: a circuit breaker type and a type other than a circuit breaker, the plurality of devices being located between the longitudinal walls according to the width axis; and
the monitoring system described above, the at least one radar unit being fixed to the enclosure.

According to other advantageous aspects of the invention, the repartition assembly comprises one or more of the following features, taken individually or in any technically possible combination:
The at least one radar unit is fixed to one of the longitudinal walls of the electrical cabinet.
The enclosure comprises a door, which, when closed, covers the longitudinal walls and the protective devices, and wherein the at least one radar unit is fixed to the door.

The invention also relates to a method of monitoring an electrical cabinet, the electrical cabinet comprising a plurality of switching devices, each device comprising a movable member configured to be displaced when an electrical fault is detected by the device or following a command from a user, each device being of one type from among the group consisting of: a circuit breaker type and a type other than a circuit breaker, the monitoring method being implemented by a monitoring system described previously, the method comprising the following steps:
when one of the movable members is displaced, an emission by one of the at least one radar units of an output signal representative of a speed of displacement of the movable member as well as a stroke of the movable member;
a reception of the output signal by the electronic control module;
a determination of the type of device to which the movable member associated with the output signal belongs by the electronic control module; and
an emission of a message representative of the type of device to which the movable member associated with the output signal belongs, by the transmission module.

The invention also relates to a computer program comprising software instructions which, when executed by a computer, implement a monitoring method as defined above.

### BRIEF DESCRIPTION OF THE DRAWINGS

The invention will become clearer on reading the following description, given solely by way of a non-limiting example, and made with reference to the drawings in which:

FIG. 1 is a schematic representation of an electric current repartition assembly according to a first embodiment of the invention;

FIG. 2 is a schematic representation of a repartition assembly according to a second embodiment of the invention;

FIG. 3 is a schematic representation of a monitoring system according to the first embodiment of the invention;

FIG. 4 is a graphic representation of types and subtypes of switching devices;

FIG. 5 is a flow chart of a monitoring method according to the invention; and

FIG. 6 is a schematic representation of a monitoring system according to a third embodiment of the invention.

### DETAILED DESCRIPTION

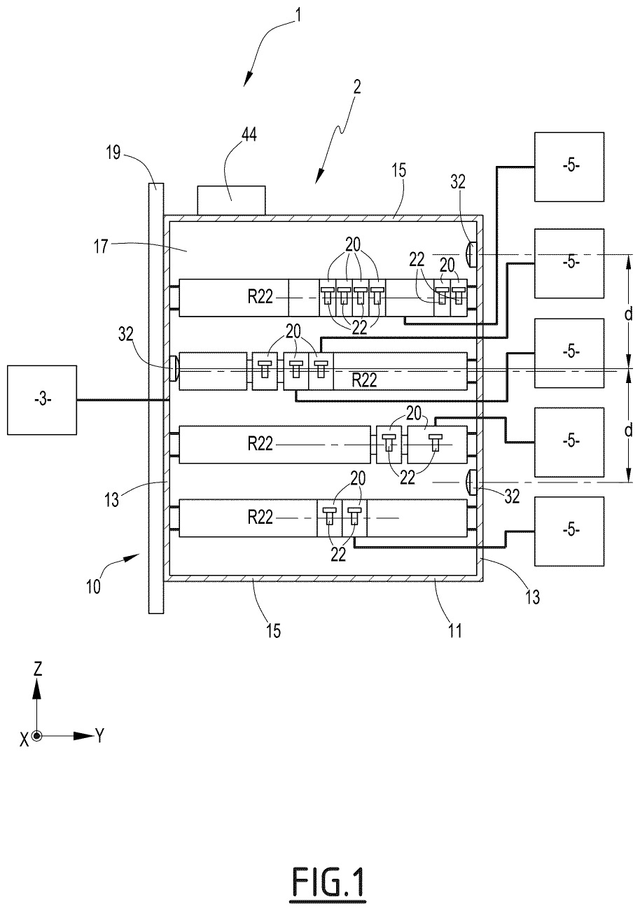

FIG. 1 is a schematic representation of a circuit 1 comprising a repartition assembly 2 for an electric current between a source 3 and a plurality of loads 5, the repartition assembly 2 being intended to be connected to the source 3 and to the plurality of loads 5.

The source 3 is, for example, a medium voltage transformer or a medium voltage to low voltage transformer. Alternatively, the source 3 is another electric current repartition system. The electric source 3 is able to supply an electric current to the repartition assembly 2, which is configured to distribute it to the loads 5.

The loads 5 consume the electric current supplied by the source 3. Preferably, the loads 5 are electric devices such that stopping their operation unexpectedly does not cause damage or risk to the safety of users of the loads 5. The loads 5 are used, for example, to improve user comfort, and are, for example, lighting devices.

The repartition assembly 2 comprises an electrical cabinet 10, also referred to simply as a cabinet. The electrical cabinet 10 is located, for example, inside a building and rests, for example, on a floor.

The electrical cabinet 10 comprises an enclosure 11, inside of which most of its components are arranged. The enclosure 11 is, for example, in the form of a box, not represented, suitable for total enclosure. The enclosure 11 comprises two longitudinal walls 13, extending parallel to a height axis Z. The longitudinal walls 13 are aligned relative to each other according to a width axis Y. The enclosure 11 also comprises two transverse walls 15, extending parallel to the width axis Y, and connecting the longitudinal walls 13 between them. The enclosure 11 further comprises a bottom 17, mechanically integral with the longitudinal walls 13 and the transverse walls 15, and a door 19, aligned with the bottom according to a depth axis X. The door 19 generally forms a removable door, or a door that can be moved relative to the longitudinal walls 13 and the transverse walls 15 between a closed configuration in which the door 19 covers the longitudinal walls 13, as well as a space delimited by the longitudinal walls 13 and the transverse walls 15, and an open configuration allowing access to the components arranged inside the enclosure, in the space delimited by the longitudinal walls 13 and the transverse walls 15.

The electrical cabinet 10 is configured to distribute electric current from the source 3 toward the plurality of loads 5. In particular, the electrical cabinet 10 is configured to interrupt the current flowing toward the plurality of loads 5. Current interruption is either voluntary, in other words, decided by a user of the electrical cabinet 10, or due to a fault, in other words, caused by an electrical fault occurring in the circuit 1. Electrical faults are abnormal electrical voltage or current values in the circuit 1. Electrical faults are, for example, overvoltages, overcurrent, short circuits, or overload faults. In order to interrupt the current flowing from the source 3 toward the plurality of loads 5, the electrical cabinet 10 comprises a plurality of switching devices 20. Each switching device 20 is connected to the source 3 and to a load 5. The devices 20 are located between the longitudinal walls 13 according to the width axis Y. More precisely, the devices 20 are arranged in the space delimited by the longitudinal walls 13 and transverse walls 15, in other words, inside the electrical cabinet 10. Thus, when the door 19 is closed, it covers the devices 20. Generally, the devices 20 are arranged inside the electrical cabinet 10 in rows parallel to the width axis Y.

Each device 20 is configured to switch between an armed configuration, in which it conducts current, and a tripped configuration, in which it does not conduct current, and isolates the source 3 and the load 5 to which it is connected.

Each device 20 comprises a movable member 22. Each movable member 22 is configured to displace when the device 20 comprising it switches to the triggered configuration. In particular, each movable member 22 pivots about an axis of rotation R22.

In the example shown in FIG. 1, the axes of rotation R22 of the movable members 22 are parallel to the width axis Y.

The switching devices 20 are of one type from among the group consisting of a circuit breaker type, and a so called other than circuit breaker type.

The circuit breaker type devices 20 are devices configured to interrupt electric current on fault. The circuit breaker type devices 20 are, for example, Miniature Circuit Breakers (MCBs), Molded Case Circuit Breakers (MCCBs) or Residual Current Devices (RCDs). When an electrical fault is detected by the circuit breaker type device 20, the device 20 switches to the tripped configuration and the movable member 22 of the circuit breaker type device 20 is displaced. The movable member 22 of a circuit breaker type device 20 is, for example, a switch lever, also known as a switch.

The other than circuit breaker type devices 20 are devices configured to interrupt electrical current voluntarily. They are configured to be remotely controlled by a user, for example a technician, and interrupt power in response to a user command. The devices 20 other than circuit breakers are, for example, remote switches or contactors. When a user commands one of the other than circuit breaker type devices 20, the other than circuit breaker type device 20 switches to the tripped configuration and the movable member 22 of the other than circuit breaker type device 20 is displaced

Advantageously, the circuit breaker type devices 20 also comprise a subtype. The subtype is, for example, a power rating, a current rating or a family. By power rating, we mean the power that the circuit breaker type device 20 is able to withstand without being damaged. By current rating, we mean the maximum current that the circuit breaker type device 20 is able to withstand without being damaged, for example less than 63 A or more than 63 A. By family, we mean a technology for interrupting the current flowing through the device, for example a family of electromechanical, hybrid or solid state interrupter devices.

The movable member 22 of the circuit breaker and other than circuit breaker devices 20 displace according to a specific speed Vₘ and a stroke Dₘ, representative of their type. Advantageously, the speed of displacement Vₘ and the stroke Dₘ of the movable members 22 of the circuit breaker type devices 20 are also representative of their subtype.

The repartition assembly 2 also comprises a monitoring system 30 for the electrical cabinet 10.

The monitoring system 30 comprises at least one radar unit 32, in this case three radar units 32. Alternatively, the monitoring system 30 comprises less than three radar units 32 or more than three radar units 32. Each of the radar units 32 is configured to emit an output signal when one of the movable members 22 is displaced, as explained in more detail below.

The radar units 32 are electromagnetic wave transceiver devices. For example, the radar units 32 comprise a transmitter and a receiver, or alternatively, a transmitter and two receivers. Advantageously, a frequency of the electromagnetic waves emitted by the radar units 32 is between 10 and 70 GHz, preferably between 20 and 30 GHz, even more preferably equal to 24 GHz. Advantageously, the radar units 32 are Doppler effect radar units.

In the example shown in FIG. 1, the radar units 32 are fixed to the longitudinal walls 13, so as to emit electromagnetic waves globally according to the width axis Y. Alternatively, not represented, the radar units 32 are all located on the same longitudinal wall 13.

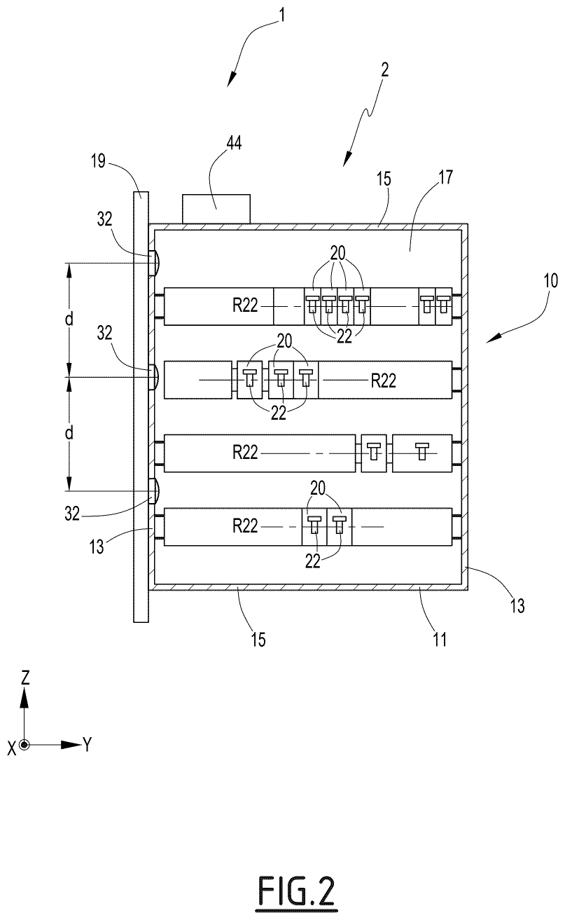

FIG. 2 represents a second embodiment of the repartition assembly 2, in which the radar units 32 are fixed to the door 19.

In practice, each radar unit 32 permanently emits a physical quantity at its output. When no movable member 22 is displaced, this quantity does not comprise any information relating to the movable members 22. When a movable member 22 is displaced, the physical quantity emitted by the at least one of the radar units 32 at its output changes and forms an output signal which is then representative of a speed of displacement Vₘ and a stroke Dₘ of the movable member 22.

Particularly advantageously, the output signal is also representative of a position within the cabinet 10 of the movable member 22 associated with the output signal, in particular a relative position between the radar unit(s) 32 having emitted the output signal, and the associated movable member 22.

Particularly advantageously, in the embodiments in FIGS. 1 and 2, the radar units 32 are separated from one another by a distance d according to the height axis Z of less than 500 mm, preferably less than 400 mm, and even more preferably equal to 300 mm. Indeed, in the examples of FIGS. 1 and 2, a single radar unit 32 does not have sufficient range to detect displacement of all the movable members 22. Several radar units 32 are therefore required to detect a displacement of all the movable members 22 included in the cabinet 10. Thus, when a movable member 22 displaces, at least one of the radar units 32 from among the radar units 32 of the monitoring system 30 emits an output signal which is representative of the speed of displacement Vₘ and the stroke Dₘ of the movable member 22. The stroke Dₘ is also referred to as the displacement amplitude of the movable member 22.

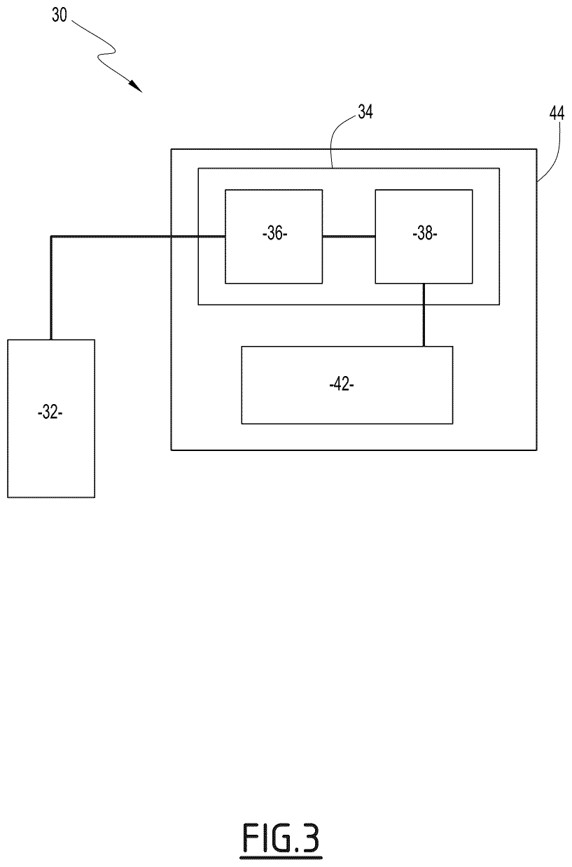

The monitoring system 30 also comprises an electronic control module 34, connected to the radar units 32, and visible in FIG. 3. The electronic control module 34 is advantageously located on or inside the cabinet 10, for example by being fixed to the enclosure 11. In the examples of FIGS. 1 and 2, the electronic control module 34 is fixed to one of the transverse walls 15.

The electronic control module 34 is configured to receive the output signal and to determine the type of device 20 to which the movable member 22 associated with the output signal belongs.

To this end, the electronic control module 34 advantageously comprises a calculation unit 36. According to a first embodiment, the calculation unit 36 is configured to calculate the speed of displacement and stroke of the movable member 22 associated with the output signal from the output signal. Advantageously, the electronic control module 34 comprises a determination unit 38, configured to receive the speed of displacement Vₘ and the stroke Dₘ of the movable member 22 associated with the output signal and to determine, from the speed of displacement Vₘ and the stroke Dₘ, the type of device 20 to which the movable member 22 associated with the output signal belongs.

Particularly advantageously, if the movable member 22 associated with the output signal is of the circuit breaker type, the electronic control module 34 is further configured to determine the subtype of the device 20. In the example of FIGS. 1 and 3, it is the determination unit 38 that is configured to determine the subtype of the device 20.

The electronic control module 34 comprises an information processing unit consisting, for example, of a memory and a processor associated with the memory, not represented.

In the example of FIG. 3, the calculation unit 36 and the determination unit 38 are each implemented in the form of software, or a software brick, executable by the processor. The memory of the electronic control module 34 is then able to store calculation software and determination software. The processor is then able to execute each of the calculation software and the determination software.

In an alternative, not represented, the calculation unit 36 and the determination unit 38 are each realized in the form of a programmable logic component, such as an FPGA (Field Programmable Gate Array), or an integrated circuit, such as an ASIC (Application Specific Integrated Circuit).

When the electronic control module 34 is realized in the form of one or more software programs, in other words, in the form of a computer program, also known as a computer program product, it is also able to be stored on a computer readable medium, not represented. The computer readable medium is, for example, a medium capable of storing electronic instructions and of being coupled to a bus of a computer system. By way of example, the readable medium is an optical disk, a magneto-optical disk, ROM memory, RAM memory, any type of non-volatile memory (FLASH or NVRAM) or a magnetic card.

The monitoring system 30 further comprises a transmission module 42, configured to emit a message representative of the type determined by the electronic control module 34, advantageously by the determination unit 38. The transmission module 42 is advantageously also realized in the form of a computer program and, in this case, it is advantageously able to be stored on the same computer readable medium as that on which the electronic control module 34 is realized. On the readable medium is then stored a computer program comprising software instructions which, when executed by a computer, implement a monitoring method described in detail later.

Advantageously, the transmission module 42 is configured to send additional information, for example, in the case of a determination that the type of device 20 is circuit breaker, information on the position of the device 20 within the cabinet 10 and/or its subtype.

Advantageously, and thus as represented in FIGS. 1 and 2, the electronic control module 34 and the transmission module 42 are grouped together in a housing 44.

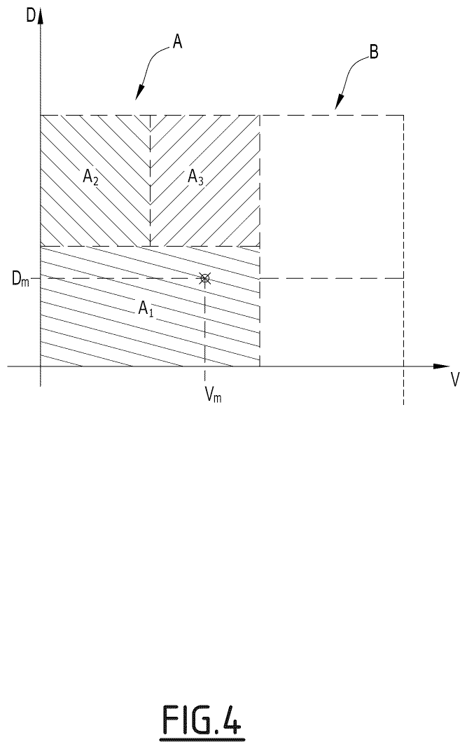

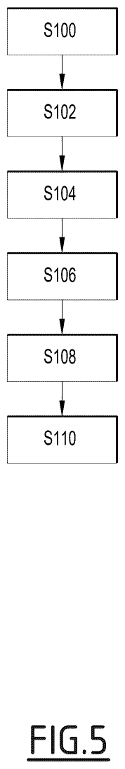

With reference to FIGS. 4 and 5, a method for monitoring the electrical cabinet 10 is described.

Initially, the electrical cabinet 10 is in a state S100, in which no movable members 22 are displaced.

A movable member 22 is displaced in the step S102.

In step S104, at least one of the radar units 32 emits an output signal representative of the speed of displacement Vₘ and the stroke Dₘ of the movable member 22.

The electronic control module 34 receives the output signal during a reception step S106.

During a determination step S108, the electronic control module 34, having received the output signal, determines the type of device 20 to which the movable member 22 associated with the output signal belongs. To do this, the calculation unit 36 calculates the speed of displacement Vₘ and the stroke Dₘ of the movable member 22 associated with the output signal, and the determination unit 38 receives the speed of displacement Vₘ and the stroke Dₘ of the movable member 22 associated with the output signal and determines the type of device 20 as being either a circuit breaker or other than a circuit breaker.

For example, the determination unit 38 compares the speed of displacement Vₘ and the stroke Dₘ of the movable member 22 obtained by the calculation unit 36 with the speed of displacement and the stroke threshold of the movable member predefined in advance, for example by the manufacturer. Thus, the determination unit 38 determines the type of device 20 comprising the movable member 22 associated with the output signal as a function of the speed of displacement Vₘ and the stroke Dₘ of the movable member 22 obtained by the calculation unit 36.

In the example of FIG. 4, the speed of displacement V and the strokes D corresponding to the circuit breaker type devices 20 are symbolized by zone A, and the speed of displacement V and the stroke D corresponding to the other than circuit breaker type devices 20 are symbolized by the zone B. The speed of displacement Vₘ and the stroke Dₘ of the movable member 22 associated with the output signal correspond to a circuit breaker type device 20. The determination unit 38 therefore determines the type of device 20 as being of the circuit breaker type.

Alternatively, not represented, the determination unit 38 compares the speed of displacement Vₘ and the stroke Dₘ of the movable member 22 obtained by the calculation unit 36 with a database of speeds of displacement and strokes of the movable members of the different devices 20 and thus determines the type of device 20 comprising the movable member 22 associated with the output signal.

Advantageously, the device 20 comprises the movable member 22 associated with the output signal being of the circuit breaker type, the determination unit 38 determines the subtype of the device 20 in a step S108.

In the example of FIG. 4, the subtypes are represented by the zones A1, A2 and A3, corresponding, for example, to an RCD, an MCB and an MCCB respectively. The speed of displacement Vₘ and the stroke Dₘ of the movable member 22 associated with the output signal therefore correspond to an RCD type device 20.

Once the type and, advantageously, the subtype have been determined by the determination unit 38, the transmission module 42 emits a message representative of the type of device comprising the movable member 22 in a transmission step S110.

The message is, for example, an alert message, comprising a text indicating that a circuit breaker type device 20 has been tripped. Advantageously, the message comprises information on the position of the device 20 inside the cabinet 10 and/or on its subtype, in this case RCD.

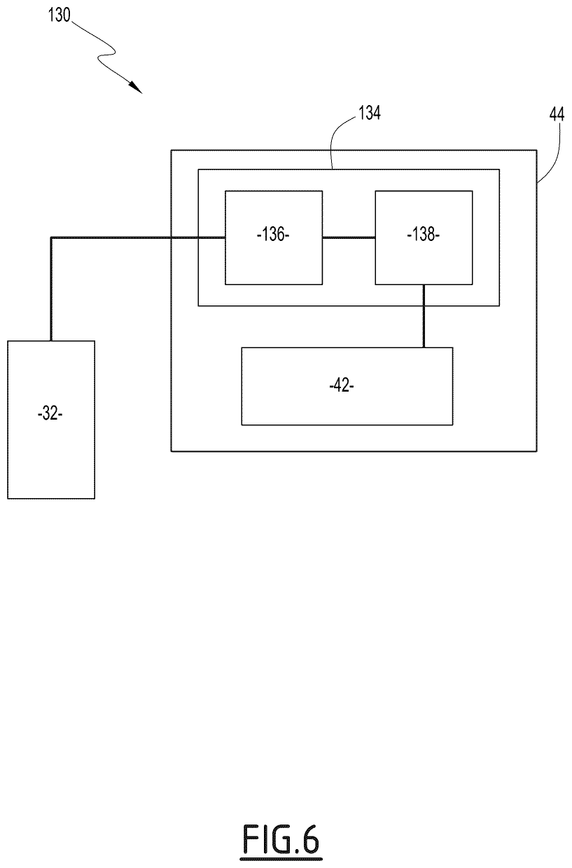

In FIG. 6 a monitoring system 130 is represented as an alternative embodiment to the monitoring system 30. The monitoring system 130 differs from the monitoring system 30 by its electronic control module 134 which replaces the electronic control module 34.

The electronic control module 134 is connected to the radar units 32 and is configured to receive the output signal and to determine the type of device 20 to which the movable member 22 associated with the output signal belongs.

The electronic control module 134 differs from the electronic control module 34 in that it comprises a calculation unit 136 and a determination unit 138, which replace the calculation unit 36 and the determination unit 38 respectively.

The calculation unit 136 is connected to the radar units 32 and is configured to receive the output signal, and to calculate a metric from the output signal. Alternatively, the calculation unit 136 calculates a plurality of metrics from the output signal. A metric is a quantity, or a series of quantities, deduced from the output signal, which allow the output signal to be described. The metrics may be directly linked to the movable member 22 associated with the output signal, as is the case for speed of displacement and stroke, or not. For example, a metric without a direct link to the movable member 22 associated with the output signal is a Fourier transform of the output signal, a simplified or filtered transform, a maximum of the Fourier transform, a form factor, characteristics relating to the peaks of the Fourier transform, such as their number, location, width. Alternatively, other metrics can also be used.

The determination unit 138 is connected to the calculation unit 136 and to the transmission module 42. The determination unit 138 is configured to receive the plurality of calculated metrics, and to determine the type of the device 20 to which the movable member 22 associated with the output signal belongs via an artificial intelligence model. The metric or, alternatively, the plurality of metrics calculated by the calculation unit 136 are input variables to the model. The type of device 20 to which the movable member 22 associated with the output signal belongs is an output variable of the model.

Advantageously, and in a manner similar to what has been described for the determination unit 38, when the determination unit 138 determines that the device 20 comprising the movable member 22 associated with the output signal is of the circuit breaker type, the artificial intelligence model of the determination unit 138 is configured to determine the subtype of the device 20. In this case, the subtype of the device 20 is another output variable of the model.

The artificial intelligence model is, for example, a random forest, or a neural network.

The neural network includes an ordered succession of layers of neurons, each of which takes its inputs from the outputs of the previous layer.

More precisely, each layer comprises neurons taking their inputs from the outputs of the neurons in the previous layer, or from the input variables for the first layer.

Alternatively, more complex neural network structures can be envisaged with a layer that can be linked to a layer further away than the immediately preceding layer.

Each neuron is also associated with an operation, in other words, a type of processing, to be performed by said neuron within the corresponding processing layer.

Each layer is linked to the other layers by a plurality of synapses. A synaptic weight is associated with each synapse, and each synapse forms a link between two neurons. This is often a real number, taking on both positive and negative values. In some cases, the synaptic weight is a complex number.

Each neuron is able to perform a weighted sum of the values received from the neurons of the preceding layer, each value then being multiplied by the respective synaptic weight of each synapse, or link, between said neuron and the neurons of the preceding layer, then to apply an activation function, typically a non-linear function, to said weighted sum, and to deliver at the output of said neuron, in particular to the neurons of the following layer connected to it, the value resulting from the application of the activation function. The activation function allows a non-linearity to be introduced into the processing performed by each neuron. The sigmoid function, the hyperbolic tangent function and the Heaviside function are examples of activation functions.

As an optional feature, each neuron is also able to apply, in addition, a multiplicative factor, also known as bias, to the output of the activation function, and the value output by said neuron is then the product of the bias value and the value output derived from the activation function.

The neural network is, for example, a convolutional neural network. A convolutional neural network is also sometimes referred to as a convolutional neural network, or CNN.

In a convolutional neural network, each neuron in the same layer presents exactly the same connection pattern as its neighboring neurons, but at different input positions. The connection pattern is called a convolution node or more often, kernel.

A fully connected layer of neurons is one in which the neurons of said layer are each connected to all the neurons of the preceding layer.

Such a type of layer is more often referred to as a “fully connected” layer and is sometimes referred to as a ‘dense” layer.

The artificial intelligence model is trained by the manufacturer before the monitoring system 130 is commissioned.

In the example of FIG. 6, the calculation unit 136 and the determination unit 138 are each realized in the form of software, or a software brick, executable by a processor, not represented. A memory, not represented, of the electronic control module 134 is then able to store calculation software and determination software. The processor is then able to execute each of the calculation software and the determination software.

In an alternative, not represented, the calculation unit 136 and the determination unit 138 are each realized in the form of a programmable logic component, such as an FPGA, or an integrated circuit, such as an ASIC.

When the electronic control module 134 is realized in the form of one or more software programs, in other words, in the form of a computer program, also referred to as a computer program product, it is also able to record on a computer readable medium, not represented. The computer readable medium is, for example, a medium capable of storing electronic instructions and of being coupled to a bus of a computer system. By way of example, the readable medium is an optical disk, a magneto-optical disk, a ROM memory, a RAM memory, any type of non-volatile memory (for example, FLASH or NVRAM) or a magnetic card. Advantageously, the transmission module 42, in the form of software, is stored on this same readable medium. A computer program comprising software instructions is stored on the readable medium. These software instructions, when executed by a computer, implement a monitoring method for the monitoring system 130, similar to that described for the monitoring system 30, except for the differences described below. The step S108 is modified as follows. During the step S108, the electronic control module 134, having received the output signal, determines the type of device 20 to which the movable member 22 associated with the output signal belongs. To do this, the calculation unit 136 calculates a metric, advantageously several metrics, which are received as input variables by the artificial intelligence model of the determination unit 138. The artificial intelligence model then determines the circuit breaker or other than circuit breaker type of the device 20 and, advantageously, the subtype of the device 20.

According to one alternative, not represented, the devices 20 are arranged in lines parallel to the height axis Z, and the axes of rotation of the movable members R22 are parallel to the height axis Z. Particularly advantageously in this case, the radar units 32 are arranged on the transverse walls 15 in such a way as to emit the electromagnetic waves globally according to the height axis Z.

In one alternative, not represented, the axis of rotation R22 of one part of the movable members 22 is parallel to the width axis Y and another part of the movable members 22 is parallel to the height axis Z.

Any feature described for one embodiment or alternative in the foregoing, may be implemented for the other embodiments and alternatives described above, insofar as technically feasible.

1. A monitoring system for an electrical cabinet, the electrical cabinet being able to be connected between an electrical source and a plurality of loads, the electrical cabinet comprising a plurality of switching devices, each device comprising a movable member configured to displace when an electrical fault is detected by the device or following a command from a user,
wherein each device is of one type from among the group consisting of: a circuit breaker type and a type other than a circuit breaker,
and wherein the system comprises:
at least one radar unit, configured so as, when one of the movable members is displaced, to emit an output signal which is representative of a speed of displacement of the movable member as well as of a stroke of the movable member;
an electronic control module, configured to receive the output signal and determine the type of device to which the movable member associated with the output signal belongs, and
a transmission module, configured to emit a message representative of the type determined by the electronic control module.

2. The monitoring system according to claim 1, wherein the electronic control module comprises:
a calculation unit configured to calculate, from the output signal, the speed of displacement and the stroke of the movable member associated with the output signal; and
a determination unit, configured to determine the type of device to which the movable member associated with the output signal belongs from the speed of displacement and the stroke calculated by the calculation unit.

3. The monitoring system according to claim 1, wherein the electronic control module comprises:
a calculation unit configured to calculate a metric from the output signal; and
a determination unit, configured to determine the type of device to which the movable member associated with the output signal belongs via an artificial intelligence model, the metric being an input variable of the model, the type of device to which the movable member associated with the output signal belongs, being an output variable of the model.

4. The monitoring system according to claim 3, wherein the artificial intelligence model is a neural network or a random forest.

5. The monitoring system according to claim 1, the output signal being further representative of a position within the cabinet of the device comprising the movable member associated with the output signal.

6. The monitoring system according to claim 1, each circuit breaker type device comprising a subtype, the electronic control module being further configured, when a movable member belonging to a circuit breaker type device displaces, to determine the subtype of the device to which the movable member associated with the output signal belongs.

7. A repartition assembly of an electric current between a source and a load, the assembly comprising:
an electrical cabinet comprising an enclosure, the enclosure comprising two longitudinal walls extending parallel to a height axis, aligned one relative to the other according to a width axis, and a plurality of switching devices, each device comprising a movable member configured to be displaced when an electrical fault is detected by the device or following a command from a user, each device being of a type from among the group consisting of: a circuit breaker type and a type other than a circuit breaker, the plurality of devices being located between the longitudinal walls according to the width axis; and
the monitoring system according to claim 1, the at least one radar unit being fixed to the enclosure.

8. The repartition assembly according to claim 7, wherein the at least one radar unit is fixed to one of the longitudinal walls of the electrical cabinet.

9. The repartition assembly according to claim 7, wherein the enclosure comprises a door, which, when it is closed, covers the longitudinal walls and the devices, and wherein the at least one radar unit is fixed to the door.

10. A method for monitoring an electrical cabinet, the electrical cabinet comprising a plurality of switching devices, each device comprising a movable member configured to be displaced when an electrical fault is detected by the device or following a command from a user, each device being of a type from among the group consisting of: a type of circuit breaker and a type other than a circuit breaker, the monitoring method being implemented by a monitoring system according to claim 1, the method comprising the following steps:
when one of the movable members is displaced, an emission, by one of the at least one radar units, of an output signal representative of a speed of displacement of the movable member as well as of a stroke of the movable member;
a reception of the output signal by the electronic control module;
a determination of the type of device to which the movable member associated with the output signal belongs, by the electronic control module; and
an emission of a message representative of the type of device to which the movable member associated with the output signal belongs, by the transmission module.

11. A computer program including software instructions which, when executed by a computer, implement a monitoring method according to claim 10.
